(19) United States
(12) Patent Application Publication
(10) Pub. No.: US 2021/0210660 A1
(43) Pub. Date: Jul. 8, 2021

(54) WAVELENGTH CONVERSION ELEMENT AND LIGHT SOURCE DEVICE

(71) Applicant: SHARP KABUSHIKI KAISHA, Sakai City, Osaka (JP)

(72) Inventors: TORU KANNO, Sakai City, Osaka (JP); SHIGERU AOMORI, Sakai City, Osaka (JP); HIDETSUGU MATSUKIYO, Sakai City, Osaka (JP)

(21) Appl. No.: 17/057,988

(22) PCT Filed: May 31, 2019
(86) PCT No.: PCT/JP2019/021673

§ 371 Date: Nov. 23, 2020

(30) Foreign Application Priority Data
May 31, 2018 (JP) 2018-104902

(51) Int. Cl. H01L 33/50; H01L 33/64

(52) U.S. Cl. CPC H01L 33/505; H01L 33/642; H01L 33/504

(57) ABSTRACT

A wavelength conversion element having improved fluorescent light emission intensity is achieved by controlling the increase in the temperature of the fluorescent layer. The wavelength conversion element includes a fluorescent layer in which phosphor particles are dispersed in a binder, the fluorescent layer including a first region and a second region, the first region being configured to be at a more elevated temperature than the second region due to an effect of excitation light, wherein the phosphor particles are constituted of a phosphor doped with a central light emitting element, and at least one of a concentration of the central light emitting element, a size of the phosphor particles, and a volume ratio of the phosphor particles with respect to the binder is configured to change from the first region to the second region of the fluorescent layer.

### TECHNICAL FIELD

The present invention relates to a light source device and a wavelength conversion element used in the light source device.

The present application claims priority to JP 2018-104902 filed m Japan on May 31, 2018, of which contents are incorporated herein by reference.

### BACKGROUND ART

It is known as prior art that a phosphor emits fluorescence in a case where an excitation light such as a blue laser is irradiated onto the phosphor.

### CITATION LIST

### Patent Literature

PTL 1: JP 2017-215507 A (published on Dec. 7, 2017)

PTL 2: WO 2014/203484 (published on Dec. 24, 2014)

PTL 3: JP 2012-119193 A (published on Jun. 21, 2012)

### SUMMARY OF INVENTION

### Technical Problem

However, the prior art described above has a problem that temperature quenching occurs due to heat generated in a case where high density excitation light is incident on a phosphor. In other words, there is a problem in that the desired fluorescent light emission intensity cannot be obtained during high power irradiation in a case where the phosphor emit light by a blue laser or the like.

An object of an aspect of the present invention is to adjust the temperature increase of a phosphor and to contribute to an improvement in fluorescent light emission intensity.

### Solution to Problem

In order to solve the problem described above, a wavelength conversion element according to an aspect of the present invention includes a fluorescent layer in which phosphor particles are dispersed in a medium containing a binder and air, the fluorescent layer including a first region and a second region, the first region being configured to be at a more elevated temperature than the second region due to an effect of excitation light, wherein the phosphor particles are constituted of a phosphor doped with a central light emitting element, and at least one of a concentration of the central light emitting element, a size of the phosphor particles, and a volume ratio of the phosphor particles with respect to the medium containing the binder and the air is configured to change from the first region to the second region of the fluorescent layer.

### Advantage Effects of Invention

According to an aspect of the present invention, it is possible to control the increase in the temperature of the fluorescent layer and to improve the fluorescent light emission intensity.

### BRIEF DESCRIPTION OF DRAWINGS

FIG. 1 is a schematic diagram illustrating a wavelength conversion element according to a prior art.

FIG. 2 is a graph illustrating an external quantum efficiency of a YAG:Ce phosphor.

FIG. 3 is a schematic diagram illustrating a wavelength conversion element according to a first embodiment of the present invention.

FIGS. 4(a) and (b) are schematic diagrams illustrating a process for producing a wavelength conversion element according to the first embodiment of the present invention.

FIG. 5 is a schematic diagram illustrating an implementation example of a wavelength conversion element according to the first embodiment of the present invention.

FIGS. 6(a) to (c) are schematic diagrams illustrating implementation examples of wavelength conversion elements according to the first embodiment of the present invention.

FIGS. 7(a) and (b) are schematic diagrams illustrating wavelength conversion elements according to a second embodiment of the present invention.

FIGS. 8(a) and (b) are schematic diagrams illustrating processes for producing wavelength conversion elements of wavelength conversion elements according to a third embodiment of the present invention.

FIGS. 9(a) and (b) are schematic diagrams illustrating wavelength conversion elements according to a fourth embodiment of the present invention.

FIGS. 10(a) to (c) are schematic diagrams illustrating wavelength conversion elements according to a fifth embodiment of the present invention.

FIG. 11(a) is a schematic diagram illustrating a light. source device according to a sixth embodiment of the present invention, and (b) and (c) are schematic diagrams illustrating a wavelength conversion element mounted on the light source device.

FIG. 12 is a schematic diagram illustrating a wavelength conversion element according to a seventh embodiment of the present invention.

FIGS. 13(a) and (b) are schematic diagrams illustrating a wavelength conversion element according to an eighth embodiment of the present invention.

FIGS. 14(a) to (c) are schematic diagrams illustrating a light source device according to a ninth embodiment of the present invention.

FIG. 15 is a schematic diagram illustrating a light source device according to a 10th embodiment of the present invention.

### DESCRIPTION OF EMBODIMENTS

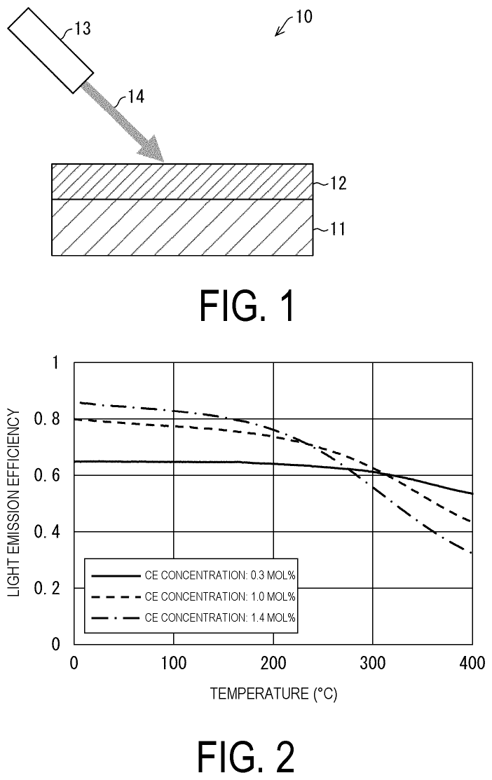

FIG. 1 illustrates a configuration of a general wavelength conversion element 10. A configuration in which a phosphor layer 12 is deposited on a substrate 11 is common. In a reflection-type optical system, excitation light 14 emitted from an excitation light source 13 irradiates the phosphor layer 12, and the phosphor layer 12 fluoresces. With respect to the problem that a desired fluorescent light emission intensity cannot be obtained during high power irradiation in a case where the phosphor emit light by a blue laser, and the like, PTL 1 proposes a configuration in which the volume density of the phosphor particles on the excitation light irradiation side of the phosphor is higher than that on the substrate side. However, with such a configuration, there is a problem that heat generation is large due to the high phosphor density on the excitation light irradiation side of the phosphor. In other words, it is necessary to consider temperature dependency of the light emission efficiency of the phosphor.

### Temperature Dependency of Light Emission Efficiency

The temperature dependency of the light emission efficiency of the phosphor is described based on external quantum efficiency of YAG:Ce (Y₃Al₅O₁₂:Ce³⁺) phosphor. As illustrated in FIG. 2, it can be seen that for a phosphor material doped with Ce (cerium) as a dopant in YAG (yttrium aluminum garnet), the temperature dependency of the light emission efficiency differs due to the difference in doping concentration of Ce. The Ce doping concentration (mol %) in an aspect of the present invention is expressed as x*100 (mol %) in a material represented by the general formula (M₁₋ₓREₓ)₃Al₅O₁₂ of the garnet-based phosphor. In the above general formula, M and RE include at least one element selected from a rare earth element group. In general, M is an element of at least one type of Sc, Y, Gd, and Lu, and RE is an element of at least one type of Ce, Eu, and Tb.

In a case where the phosphor is irradiated with excitation light, the fluorescent light emission is obtained, and at the same time, part of the excitation light is converted to thermal energy, and thus the irradiation spot portion of the phosphor has high temperature. Thermal radiation can generally be described by the following equation.

Q=A*ε*σ*(T_{A}̂4−T_{B}̂4)

Here, Q is the radiant heat, A is the radial area, ε is the emissivity, σ is the Stefan Boltzmann constant, T_{A} denotes the temperature of the radial, and T_{B}. In denotes the ambient temperature.

It is known that the light emission efficiency of a phosphor is affected by the temperature of the phosphor, and as illustrated in FIG. 2, the light emission efficiency decreases as the temperature increases. In order to obtain a stronger (brighter) fluorescent light emission, the irradiation intensity of the excitation light 14 needs to be increased, and in this case, increase of the temperature of the phosphor layer 12 may not be sufficiently suppressed depending on the cooling condition.

It is also known that the temperature characteristic of a phosphor varies with the concentration of the central light emitting element (Ce in the present embodiment). Typically, the Ce concentration of a YAG:Ce phosphor that is commercially available often uses a concentration of high light emission efficiency in a case of being used in an ambient temperature (for example, from approximately 1.4 to 1.5 mol %). This is because in a YAG phosphor with a low concentration of Ce, the internal quantum efficiency increases, but the absorption rate of the excitation light is low, the external quantum efficiency, which is important as a wavelength conversion element, is the optimal value near the Ce concentration of 1.5 mol %. In a case where the phosphor temperature of the irradiation spot is in a region exceeding 250° C. by high density and high intensity excitation light irradiation, the light emission efficiency decreases in a typical YAG:Ce phosphor (Ce concentration of 1.4 mol %) (see FIG. 2). However, a YAG:Ce phosphor with a low Ce concentration (for example, from approximately 0.3 to 1.0 mol %) has a small temperature dependency of the light emission efficiency, and the light emission efficiency may be reversed with the high concentration of light emitting bodies compared to in the low temperature. For example, the low-temperature region (50° C. to 100° C.) and the high-temperature region (250° C. to 350° C.) are compared in the graph of FIG. 2. In the low-temperature region, the higher the Ce concentration of the YAG:Ce phosphor, the higher the light emission efficiency tends to be, but in the high temperature region, the lower the Ce concentration, the higher the light emission efficiency tends to be. The present invention will be described in each embodiment in consideration of such a trend.

Since in excitation by laser light, the excitation density is high resulting in high temperature, it is desirable to use an oxide-based or a nitride-based phosphor with high heat resistance. It is more desirable to use one, as a phosphor, that the temperature dependency of the light emission efficiency is great. For use as a light source device, fluorescent light may be other than white light such as blue, green, or red.

For example, CaAlSiN₃:Eu²⁺ can be used as a phosphor that converts near ultraviolet light to red light. For example, Ca-α-SiAlON:Eu²⁺ can be used as a phosphor that converts near ultraviolet light to yellow light. For example, β-SiAlON:Eu²⁺ or Lu₃Al₅O₁₂:Ce³⁺ (LuAG:Ce) can be used as a phosphor that converts near ultraviolet light to green light. Examples of phosphors that convert near ultraviolet light to blue light include (Sr, Ca, Ba, Mg)₁₀(PO₄)₆C₁₂:Eu, BaMgAl₁₀O₁₇:Eu²⁺, and (Sr, Ba)₃MgSi₂O₈:Eu²⁺ can be used.

The fluorescent member may also be formed to include two phosphors that convert the excitation light of near ultraviolet light into yellow and blue light. As a result, the fluorescent colors of yellow light and blue light emitted from the fluorescent member can be mixed to obtain pseudo-white light.

In the following, an example of a YAG:Ce phosphor will be described in each embodiment of the present invention as a preferred embodiment.

### First Embodiment

### Configuration of Wavelength Conversion Element

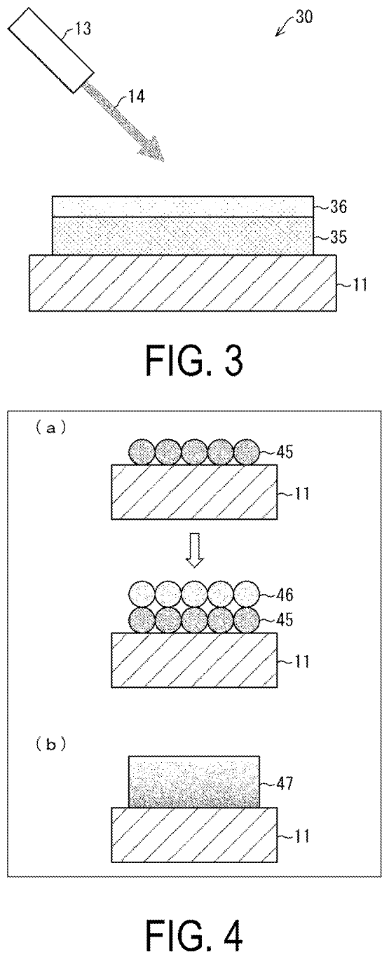

An embodiment of the present invention will be described in detail below. FIG. 3 illustrates a schematic diagram of a wavelength conversion element 30 according to a first embodiment of the present invention. The configuration of a phosphor layer differs in comparison to the configuration of the general wavelength conversion element 10 illustrated in FIG. 1. In the phosphor layer of the wavelength conversion element 30, a Ce doped YAG phosphor layer 35 is deposited on a substrate 11, and a low Ce concentration YAG phosphor layer 36 is deposited thereon. In other words, the phosphor layer 36 on a surface irradiated with an excitation light 14 has a configuration in which the concentration of Ce, which is the central light emitting element, is lower than that of the phosphor layer 35 on the substrate side. Hereinafter, the side on which the excitation light 14 is irradiated is referred to as a “first region”, and the other side is referred to as a second region. In this example, an example is illustrated in which the phosphor layer is composed of at least two regions (first region and second region) with different Ce concentrations, but the embodiment is not limited to a two-layer structure, but may have other multilayer structures. In a case of being constituted by a multilayer structure, the layer deposited on the substrate 11 corresponds to the second region, and the irradiation surface side irradiated with the excitation light 14 corresponds to the first region.

### Manufacturing Process for Wavelength Conversion Element

FIG. 4 illustrates an example of a manufacturing process for the wavelength conversion element 30 according to the first embodiment. The substrate 11 can be an aluminum substrate. In order to increase the fluorescent light emission intensity, a highly reflective film such as silver is preferably coated on the aluminum substrate. In other embodiments, highly reflective alumina substrates, white full scattering substrates, etc. may be used. The material of the substrate 11 preferably has a high thermal conductivity such as metal, and is not particularly limited to the materials described above.

In FIG. 4(a), an example of manufacturing by sedimentation application is illustrated. A high Ce concentration YAG phosphor 45 to form a second layer (corresponding to the second region) is applied onto the substrate 11, and then a low Ce concentration YAG phosphor 46 of the first layer (corresponding to the first region) is applied. The manufacturing method is not limited to sedimentation application, and other methods may be used. As an example of a yellow phosphor doped with Ce in YAG, the first layer can apply YAG phosphor with a Ce concentration of 0.5 mol % with a film thickness of 25 μm. In the second layer, a YAG phosphor with a Ce concentration of 1.4 mol % can be applied with a film thickness of 25 μm. For both, the average particle size D50 is preferably approximately 8 μm. In this case, the first region and the second region may be formed from three to four layers of YAG phosphor. In such an embodiment, a phosphor layer having a total film thickness of approximately 50 μm can be configured. The number of layers is not limited to two layers, and may be three or more layers.

The phosphor layer can also have a configuration with a concentration gradient of Ce as illustrated in FIG. 4(b). The Ce concentration gradient YAG phosphor layer 47 has a configuration in which the Ce concentration on the side (corresponding to the second region) of the substrate 11 is high, and the Ce concentration on the excitation light irradiation surface side (corresponding to the first region) is low.

In any case, by providing phosphors with different central light emitting element concentrations on the excitation light emission surface side and the substrate side, light emission can be obtained by a phosphor with good light emission efficiency in each temperature range, and a brighter light source device can be achieved compared to a case where a single phosphor is used.

### Implementation Example of Wavelength Conversion Element

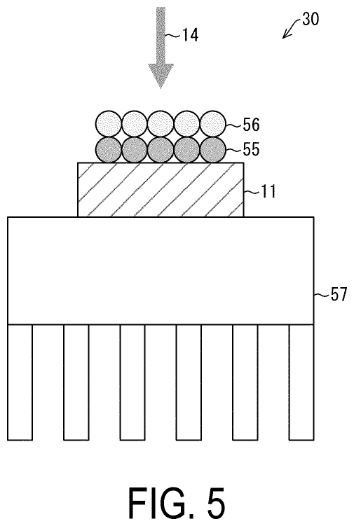

FIG. 5 illustrates an example of the implementation of the wavelength conversion element 30 according to the present embodiment. A high Ce concentration YAG phosphor 55 is deposited on the substrate 11 (corresponding to the second region), and a tow Ce concentration YAG phosphor 56 is deposited thereon (corresponding to the first region). The substrate 11 can be cooled by direct and stationary contact with a heat sink 57.

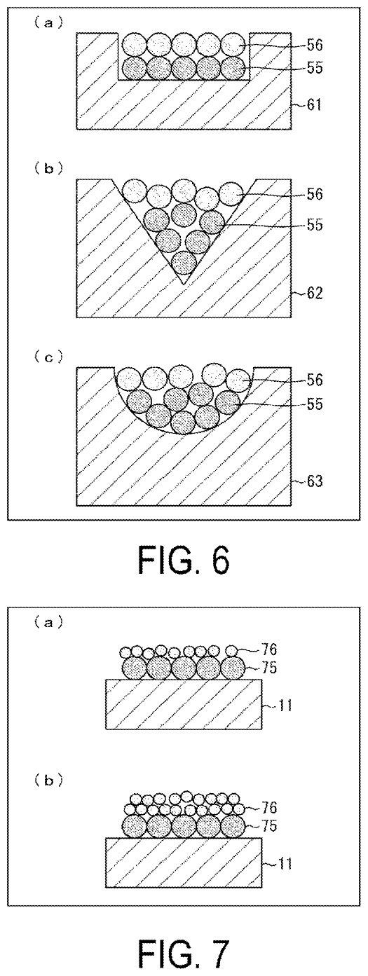

FIGS. 6(a) to (c) illustrate other implementation examples of the wavelength conversion element 30 according to the present embodiment. A substrate 61, 62, or 63 of various shapes can be used in place of the substrate 11 in FIG. 5. A high Cc concentration YAG phosphor 55 is deposited on a substrate with such various shapes, and a low Ce concentration YAG phosphor 56 is deposited thereon. By depositing a phosphor on a substrate with such a shape, the heat dissipation effect on the surface of the substrate is expected. The shape of the substrate is not limited to the shapes of the substrates 61, 62, and 63, and various shapes can be adopted from the perspective of the heat dissipation effect. As illustrated in FIG. 5, the substrate can be further cooled by direct and stationary contact with the heat sink 57.

### Second Embodiment

Another embodiment of the present invention will be described below. Note that, for convenience of explanation, components having the same function as those described in the above-described embodiment will be denoted by the same reference signs, and descriptions of those components will be omitted.

### Configuration of Wavelength Conversion Element

FIG. 7 illustrates a case in which the average particle sizes of the phosphor constituting the layer on the irradiation surface side of the wavelength conversion element and the phosphor constituting the layer on the substrate 11 side are different from each other. As illustrated in FIG. 7(a), the average particle size of a high Ce concentration YAG phosphor 75 on the layer of the substrate 11 side (corresponding to the second region) is relatively larger than the average particle size of a low Ce concentration YAG phosphor 76 on the layer of the irradiation surface side of the excitation light (corresponding to the first region). As illustrated in FIG. 7(b), a plurality of layers of the low Ce concentration YAG phosphor 76 may be layered. In a preferred embodiment, the average particle size of the low Ce concentration YAG phosphor 76 may be approximately 5 μm, and the average particle size of the high Ce concentration YAG phosphor 75 may be approximately 15 μm. The total film thickness is preferably 20 to 100 μm.

From the perspective of internal quantum efficiency, it is known that as the particle size of the phosphor increases, the light emission efficiency of the phosphor increases in general. Since the light emission efficiency of the irradiation surface side (first region) is relatively low, it is possible to suppress heat generation. By making the light emission surface side (first region) that becomes high temperature at a relatively small phosphor, color unevenness on the light emission surface of the phosphor can be reduced.

### Third Embodiment

Another embodiment of the present invention will be described below, Note that, for convenience of explanation, components having the same function as those described in the above-described embodiments will be denoted by the same reference signs, and descriptions of those components will be omitted.

### Configuration of Wavelength Conversion Element

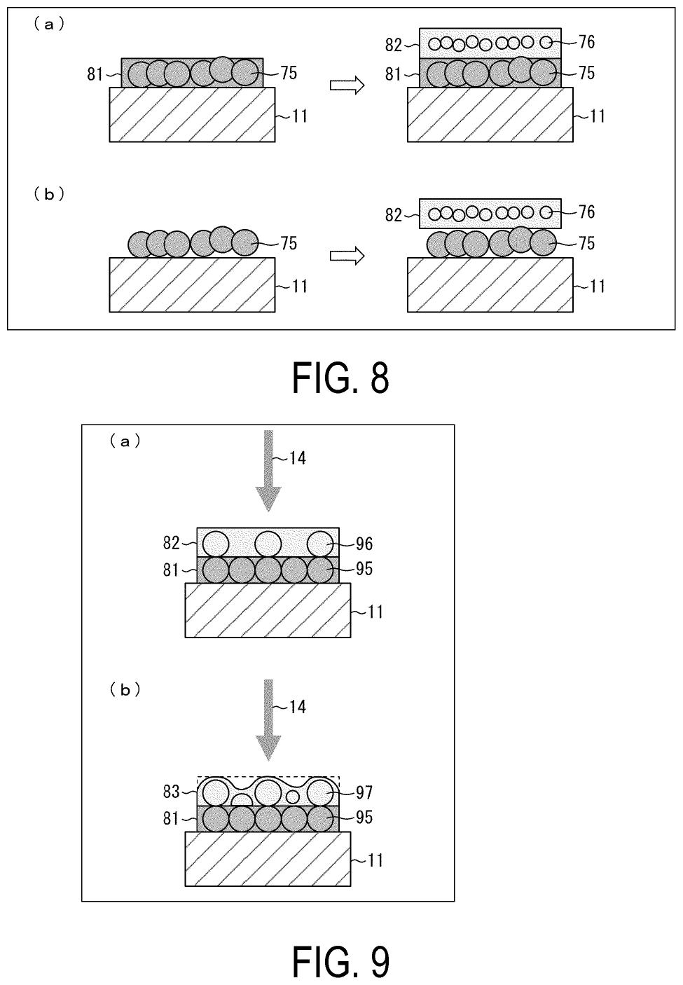

FIG. 8 illustrates a wavelength conversion element according to a third embodiment. The phosphor layer of the present embodiment is preferably composed of a phosphor and a binder that covers the phosphor. The binder is preferably a medium containing voids. In another embodiment, the medium may be a binder that does not include voids. In a preferred embodiment, the phosphor is dispersed in the binder containing the voids. The proportion of phosphor in the phosphor layer is preferably approximately 50 to 75% in volume ratio with respect to the phosphor layer. In a case where the amount of phosphor is small, the light emitting portion will be small, so it is preferable that the phosphor be at least 50% or more. Assuming that the shape of phosphor to be perfectly spherical, and further assuming that the particle size of the phosphor is a single particle size, it can be assumed that the phosphor density will be about 74% (≈π/√18) in a case where the most closely-packed structure is achieved. In a preferred embodiment, the phosphor is not perfectly spherical in shape, and the phosphor particle size also has a particle size distribution. Therefore, the proportion of phosphor in the phosphor layer is preferably approximately 75% at the maximum in a volume ratio with respect to the phosphor layer.

Because the binder covers the phosphor but contains voids in the binder, there are many bubbles in the process, and there may be case where the amount of binder that connects the phosphors is small. The phosphor layer may be a phosphor layer of a porous structure such that the binder and the voids are in contact with each other around the phosphor. In the phosphor layer constituted of the binder that contains the voids, the amount of binder may be configured to decrease from the first region to the second region. In another preferred embodiment, as the schematic diagrams illustrated in FIG. 4(a) and FIGS. 5 to 7, which illustrate the first and second embodiments, the amount of binder may be zero. At least the excitation light irradiation surface side (first region) is preferably constituted by a phosphor/medium. The presence of voids in the binder may increase the scattering of light within the phosphor layer due to the smaller refractive index of the phosphor layer than the binder that does not contain voids. For example, the refractive index of YAG is 1.82, the refractive index of alumina (inorganic binder) is 1.77, the refractive index of silicone rubber (organic binder) is 1.57, and the refractive index of vacuum or gas is approximately 1. Thus, the presence of voids having a large refractive index difference with the phosphor increases the reflection at the phosphor/void interface.

The binder that constitutes the phosphor layer is preferably an organic material represented by a silicone resin or a transparent inorganic material such as alumina or silica as an inorganic binder. Such a phosphor layer can be formed by a common dispenser, screen printing, or other printing method. In particular, in a case where there is no need to form a pattern shape, a so-called dip method for immersing in a solution such as alumina sol, silica sol, or the like may be used.

FIG. 8(a) illustrates a state in which the second layer (second region) is applied on the substrate 11, and the first layer (first region) is applied thereon. The second layer is constituted by a high Ce concentration YAG phosphor 75/medium 81 by a printing method or the like, and the first layer is constituted by a low Ce concentration YAG phosphor 76/medium 82 likewise. FIG. 8(b) illustrates a state where the second layer is precipitated and applied onto the substrate 11, and the first layer is applied thereon by a printing method or a dip method. The second layer (second region) is constituted by a high Ce concentration YAG phosphor 75, and the first layer (first region) is constituted by a low Ce concentration YAG phosphor 76/medium 82. In the configuration illustrated in FIG. 8(b), the second layer (second region) is a phosphor layer in which no binder is present.

By using a binder having a higher thermal conductivity than the air, heat dissipation is improved by configuring at least the excitation light irradiation surface side (first region) from the phosphor/binder containing medium.

### Fourth Embodiment

Another embodiment of the present invention will be described below. Note that, for convenience of explanation, components having the same function as those described in the above-described embodiments will be denoted by the same reference signs, and descriptions of those components will be omitted.

### Configuration of Wavelength Conversion Element

FIG. 9 illustrates a wavelength conversion element according to a fourth embodiment. The phosphor layer of the present embodiment is preferably composed of a phosphor and a medium covering the phosphor. Similar to the third embodiment, the medium is a matrix containing at least a binder and air. In a preferred embodiment, the phosphor is dispersed in the medium containing the binder and air. The phosphor layer of the present embodiment has a difference in the density of the phosphor compared to the third embodiment. At least, the excitation light irradiation surface side (first region) preferably has a small density of phosphor with respect to the medium. In the example illustrated in FIG. 9(a), a second layer (second region) is deposited on the substrate 11, and a first layer (first region) is deposited on the second layer. The density of a low Ce concentration YAG phosphor 96 is low in the first layer (density of the medium 82 is high), and the density of a high Ce concentration YAG phosphor 95 is high in the second layer (the density of the medium 81 is low).

The proportion (light emission points) occupied by the low Ce concentration YAG phosphor 96 is small on the excitation light irradiation surface side (first region), so heat. generation caused by excitation light can be suppressed.

As another embodiment, as illustrated in FIG. 9(b), a concave-convex structure can be imparted to the surface of the first layer, and the light extraction efficiency can be improved. In a case where the surface of the excitation light irradiation surface side (first region) is flat, light quantity loss occurs because a portion of the incident light is totally reflected. In the case of the surface with the concavo-convex structure as illustrated in FIG. 9(b), there is little effect of total reflection and light quantity loss is unlikely to occur. In order to impart a concave-convex structure to the surface of the first layer, it is preferable that the particle sizes of the low Ce concentration YAG phosphor 97 contained in the medium 83 in the first layer be made varying in size from small to large. In other words, as illustrated by the dotted line, the medium 83 in FIG. 9(b) is constituted by a medium in which a large amount of air is disposed on the irradiation surface side.

### Fifth Embodiment

Another embodiment of the present invention will be described below. Note that, for convenience of explanation, components having the same function as those described in the above-described embodiments will be denoted by the same reference signs, and descriptions of those components will be omitted.

### Configuration of Wavelength Conversion Element

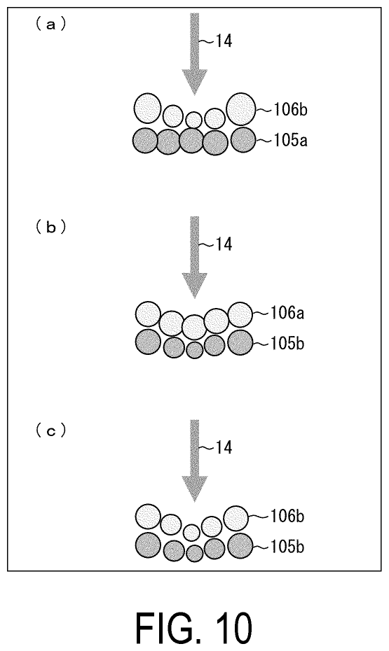

FIGS. 10(a) to 10(c) illustrate a wavelength conversion element according to a fifth embodiment. In the phosphor layer of the present embodiment, the irradiation spot portion of the excitation light 14 is thin in the phosphor layer, and the phosphor layer is thick except for the irradiation spot. In a preferred embodiment, the central portion of the phosphor layer is irradiated with the excitation light 14, so the vicinity of the central portion of the phosphor layer is configured to be thinner, and the peripheral portion is configured to be thicker. In such an embodiment, the central portion is referred to as a first region and the peripheral portion is referred to as a second region. In FIG. 10, for both a high Ce concentration YAG phosphor 105 and a low Ce concentration YAG phosphor 106, those configured with the same particle size are designated with the suffix “a” as 105a or 106a, Similarly, for both the high Ce concentration YAG phosphor 105 and the low Ce concentration YAG phosphor 106, those configured with different particle sizes are designated with the suffix “b” as 105b or 106b.

Referring to FIG. 10(a), the second layer is composed of a high Ce concentration YAG phosphor 105a having a solid coating and uniform film thickness, and the first layer is composed of a low Ce concentration YAG phosphor 106b with a thin film thickness of the irradiation spot portion (first region). Referring to FIG. 10(b), the second layer is composed of a high Ce concentration YAG phosphor 105b having a thin film thickness of the irradiation spot portion (first region), and the first layer is composed of a low Ce concentration YAG phosphor 106a having a solid coating and uniform film thickness. Referring to FIG. 10(c), both the second layer and the first layer are respectively composed of a high Ce concentration YAG phosphor 105b and a low Ce concentration YAG phosphor 106b having a thin film thickness of the irradiation spot portion (first region).

In the manufacturing process, an in-plane distribution can be provided with the phosphor particle size to be applied or the coating thickness. It is also preferable to differentiate the film thickness distribution by providing a plurality of layers in both the first layer and the second layer.

Because the irradiation spot is small with respect to the size of the phosphor layer, by using the configuration of the fifth embodiment, the heat generation at the irradiated locations can be suppressed, and heat can be dissipated to the peripheral portion (second region).

### Sixth Embodiment

Another embodiment of the present invention will be described below. Note that, for convenience of explanation, components having the same function as those described in the above-described embodiments will be denoted by the same reference signs, and descriptions of those components will be omitted.

### Configuration of Light Source Device

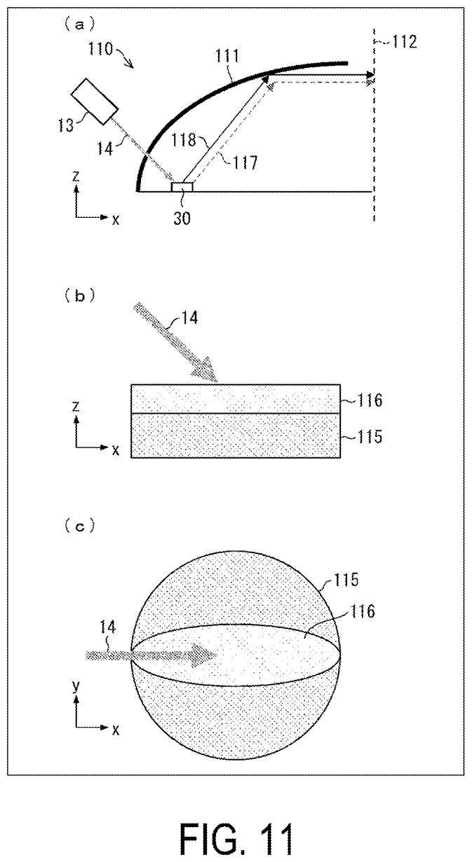

FIG. 11(a) illustrates a schematic diagram of a light source device 110 according to a sixth embodiment of the present invention. The light source device 110 is preferably a reflection-type laser headlight. The excitation light source 13 is preferably a blue laser light source that emits excitation light 14 having a wavelength that excites the phosphor layer of the wavelength conversion element 30. A reflector 111 is preferably constituted by a semi-paraboloid mirror. The paraboloid is preferably a half paraboloid, parallel to the xy plane, divided into two parts, and the inner surface thereof is preferably a mirror. There is a hole in the reflector 111 through which the excitation light 14 passes. The wavelength conversion element 30 is excited by the blue excitation light 14, and emits a fluorescent light emission 117 in the long wavelength region (yellow wavelength) of the visible light. The excitation light 14 also becomes diffuse reflected light 118 against the wavelength conversion element 30. The wavelength conversion element 30 is disposed at a focal point of the paraboloid. Since the wavelength conversion element 30 is at the focal point of the paraboloid mirror, the fluorescent light emission 117 emitted from the wavelength conversion element 30 and the diffuse reflected light 118 reflect against the reflector 111, the uniformly travel to the light emission face 112. White light that is mixed with the fluorescent light emission 117 and the diffuse reflected light 118 exits from the light emission face 112 as parallel light. In FIG. 11(a), the wavelength conversion element 30 according to the first embodiment is disposed at the focal point of the paraboloid, but in other preferred embodiments, the wavelength conversion element according to the second to fifth embodiments may be used.

FIG. 11(b) illustrates a schematic diagram of a wavelength conversion element located at the focal point of the paraboloid. In the wavelength conversion element, the layer on the irradiation surface side of the excitation light (first region) is constituted by a low Ce concentration YAG phosphor 116, and the layer on the substrate side (second region) is constituted by a high Ce concentration YAG phosphor 115.

FIG. 11(c) illustrates an example of a plan view parallel to the xy plane of the wavelength conversion element. In an optical system in which the excitation light 14 is incident from an oblique angle in the xz plane as in the sixth embodiment, the layer of the low Ce concentration YAG phosphor 116 of the first layer may have an in-plane anisotropic shape in the xy plane, such as having an elongated length with respect o the incident direction.

By disposing the low Ce concentration YAG phosphor 116 in the layer (first region) on the irradiation surface side of the excitation light, light emission at a higher brightness is possible than in the prior art.

### Seventh Embodiment

Another embodiment of the present invention will be described below. Note that, for convenience of explanation, components having the same function as those described in the above-described embodiments will be denoted by the same reference signs, and descriptions of those components will be omitted.

### Configuration of Wavelength Conversion Element

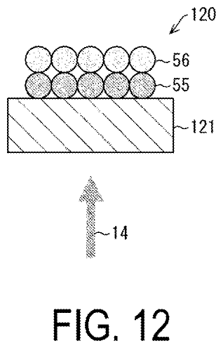

FIG. 12 illustrates a wavelength conversion element 120 according to a seventh embodiment. In the seventh embodiment, the wavelength conversion element 120 assumed to be mounted to a transmission-type laser headlight will be described. For example, a transmission-type laser headlight is disclosed in PTL 2 (WO 2014/203484) or the like. In a transmission-type lamp, excitation light is irradiated from the substrate side to fluoresce light. In FIG. 12, an example is illustrated in which a high Ce concentration YAG phosphor 55 is deposited on a transmissive heat sink substrate 121 (second region), and a low Ce concentration YAG phosphor 56 is deposited thereon (first region). The excitation light 14 is irradiated from a face (second region) of the transmissive heat sink substrate 121 opposite the surface on which the phosphor is deposited. The transmissive heat sink substrate 121 preferably includes a heat sink function. As disclosed in PTL 3 (JP 2012-119193 A), in a case where a fluorescent film is deposited on a transmission-type heat sink substrate, it is known that the heat sink side has high heat dissipation in a case where excitation light is incident from the heat sink side. Since the transmissive heat sink substrate 121 used in the wavelength conversion element 120 is provided with a heat sink function, the high Ce concentration YAG phosphor 55 is preferably deposited on the irradiation surface side (second region) irradiated by the excitation light. The excitation light is irradiated from the irradiation surface side (second region), and heat on the irradiation surface side (second region) is dissipated to the transmissive heat sink substrate 121, thereby causing the first region to have a higher temperature than the second region. Therefore, the low Ce concentration YAG phosphor 56 is preferably deposited in the first region.

In the seventh embodiment, the high Cc concentration YAG phosphor 55 and the low Ce concentration YAG phosphor 56 having the same particle size as that of the first embodiment are exemplified, but phosphors having different particle sizes or volume densities as indicated in the other second to fifth embodiments may be used.

### Eighth Embodiment

Another embodiment of the present invention will be described below. Note that, for convenience of explanation, components having the same function as those described in the above-described embodiments will be denoted by the same reference signs, and descriptions of those components will be omitted.

### Configuration of Wavelength Conversion Element

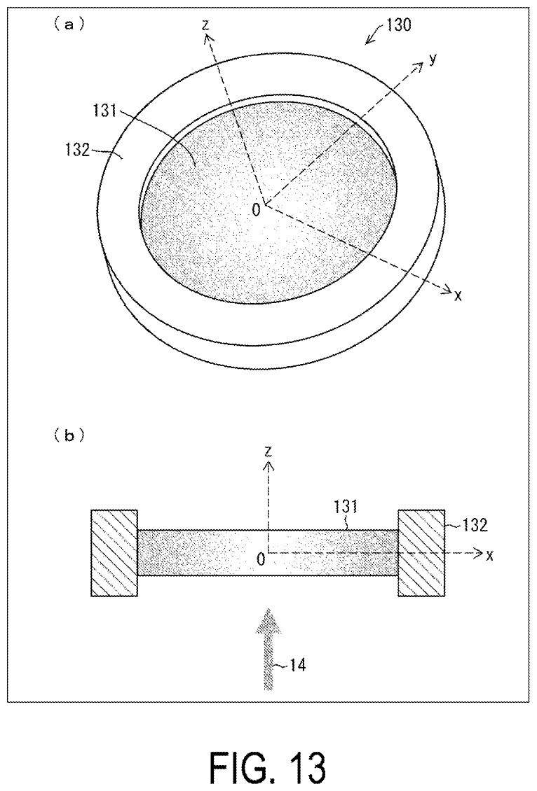

FIG. 13 illustrates a wavelength conversion element 130 according to an eighth embodiment. The wavelength conversion element 130 includes a disc type fluorescent layer 131 and a heat sink frame 132 that surrounds and holds a peripheral portion or edge of the fluorescent layer 131. As illustrated in FIG. 13(a), for convenience, the center portion of the disc type fluorescent layer 131 is defined as the origin point (0), the plane extending in the planar direction of the disk from the origin is defined as the xy plane, and the direction extending vertically from the light emission surface of the disc type fluorescent layer 131 is defined as the z-axis.

In the eighth embodiment, the disc type fluorescent layer 131 is preferably a YAG phosphor having a concentration gradient of Ce, which is a central light emitting element. As illustrated in FIG. 13(b), in a case where the excitation light 14 is irradiated on the fluorescent layer 131, because the center of the irradiating portion gets at an elevated temperature, the Ce concentration of the fluorescent layer 131 in the vicinity of the origin point (0) (first region) is preferably low. It is preferable that the Ce concentration increases as the value of the radius (√(x̂2+ŷ2)) in the xy plane increases away from the origin point (0). Consequently, in the peripheral portion or edge (second region) of the disc type fluorescent layer 131, the Ce concentration is higher than in the center. The edge (second region) of the disk type fluorescent layer 131 holds the fluorescent layer 131 with the heat sink frame 132 and has high heat dissipation. Heat generated in the center (first region) of the disk type fluorescent layer 131 is transferred to the peripheral portion (second region), and heat can be dissipated to the heat sink at the edge. Due to the heat dissipation action of the heat sink, by the excitation light 14 being irradiated to the center (first region) of the fluorescent layer 131, and the heat in the second region being dissipated into the heat sink frame 132, the first region gets a higher temperature than the second region.

### Ninth Embodiment

Another embodiment of the present invention will be described below. Note that, for convenience of explanation, components having the same function as those described in the above-described embodiments will be denoted by the same reference signs, and descriptions of those components will be omitted.

### Configuration of Light Source Device

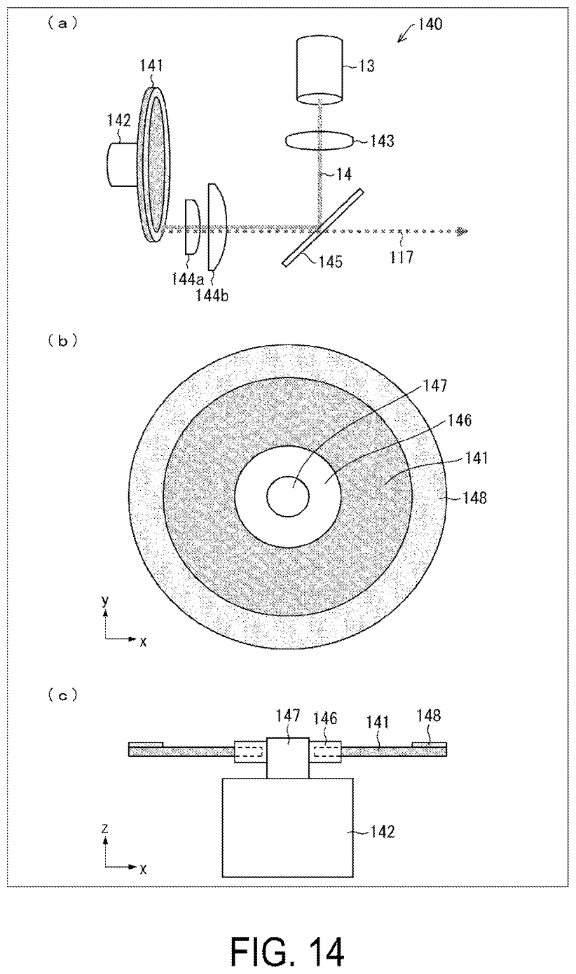

FIG. 14(a) is a schematic diagram of a light source device 140 according to a ninth embodiment. The light source device 140 is preferably used for a projector or the like. In the light source device 140, the excitation light source 13 is preferably a blue laser light source that emits excitation light 14 having a wavelength that excites a phosphor layer 148. In a preferred embodiment, a blue laser diode that excites a phosphor such as YAG or LuAG is used. The excitation light 14 irradiated to the phosphor layer 148 may pass through the lens 143, 144a, and 144b on the optical path. A mirror 145 may be disposed on the optical path of the excitation light 14. The mirror 145 is preferably a semi-mirror (half mirror).

The phosphor layer 148 is deposited on a fluorescent wheel 141. FIG. 14(b) illustrates a plan view (xy plane) of the fluorescent wheel 141, and FIG. 14(c) illustrates a cross-sectional view (xz plane) of the fluorescent wheel 141. In a preferred embodiment, the phosphor layer 148 is deposited on the peripheral portion of the surface of the fluorescent wheel 141. The fluorescent wheel 141 is fixed to a rotation shaft 147 of a drive device 142 by a wheel fixing tool 146. The drive device 142 is preferably a motor, and the fluorescent wheel 141, which is fixed with the fixing tool 146 to the rotation shaft 147, which is the rotating shaft of the motor, rotates with the rotation of the motor.

The phosphor layer 148 deposited on the peripheral portion on the surface of the fluorescent wheel 141 receives excitation light and emits fluorescent light emission 117, and passes through the mirror 145 to emit fluorescence. The phosphor layer 148 emits the fluorescent light emission 117 while rotating at any time due to rotation of the fluorescent wheel 141.

In a preferred embodiment, the phosphor layer 148 can be deposited on a fluorescent wheel 141 having a substrate with a high Ce concentration YAG phosphor 55 and a low Ce concentration YAG phosphor 56 having the same particle size as described in the first embodiment. A high Ce concentration YAG phosphor 55, which serves as the second layer (second region), is deposited on the fluorescent wheel 141 serving as the substrate, and a low Ce concentration YAG phosphor 56 is deposited thereon (first region), thereby allowing a higher brightness light emission than in the prior art. In another preferred embodiment, phosphors having different particle sizes or volume densities as illustrated in the second to fifth embodiments may be used.

### 10th Embodiment

Another embodiment of the present invention will be described below. Note that, for convenience of explanation, components having the same function as those described in the above-described embodiments will be denoted by the same reference signs, and descriptions of those components will be omitted.

### Configuration of Light Source Device

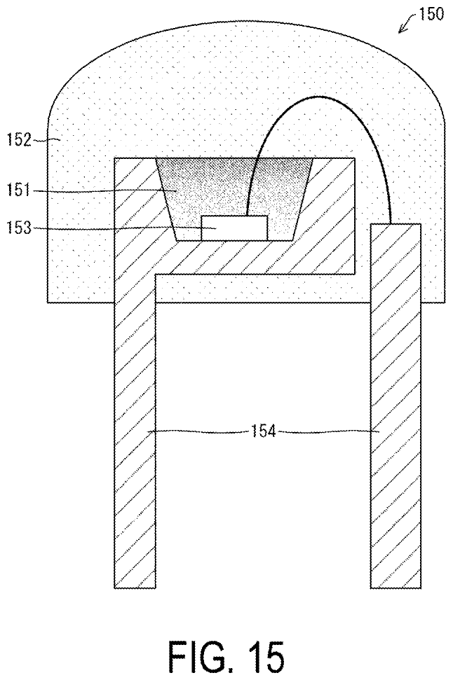

FIG. 15 illustrates a schematic diagram of a light source device 150 according to a 10th embodiment. The light source device 150 is preferably a bullet-shaped light emitting diode (LED). The light source device 150 includes lead wires 154 that form a pair of electrode terminals, and an excitation light source 153 that emits excitation light and is electrically connected to the pair of lead wires 154. The excitation light source 153 is preferably a light emitting diode (LED) element. As illustrated in FIG. 15, a light emitting diode (LED) element (excitation light source) 153 is disposed on a bottom surface of a recessed portion provided in one of the pair of lead wires 154 with its primary light emission orientation oriented upward. The recessed portion is preferably formed so as to surround the outer periphery of the light emitting diode (LED) element 153 disposed on the bottom surface of the recessed portion by a mortar shaped inclined surface. A wavelength conversion element is provided in the recessed portion so as to cover the light emitting diode (LED) element 153 disposed on the bottom surface of the recessed portion. The fluorescent layer 151 of the wavelength conversion element preferably has a first surface (bottom surface) and a second surface (top surface) that are opposite to each other in the thickness direction, the first region is preferably on the first surface (bottom surface) side, and the second region is preferably on the second surface (top surface) side. As illustrated in FIG. 15, the first surface (bottom surface) faces the light emitting diode (LED) element 153 side, and by irradiating excitation light from the first surface (bottom surface) side, the first region is at an elevated temperature than in the second region. As illustrated in FIG. 15, a resin 152 is packaged on the second surface (top surface) of the fluorescent layer 151 so as to cover the recessed portion formed in the lead wire.

In a preferred embodiment, the fluorescent layer 151 can be deposited with the low Ce concentration YAG phosphor 56 and the high Ce concentration YAG phosphor 55 with the same particle size as described in the first embodiment. The low Ce concentration YAG phosphor 56, which serves as the first layer (first region), is deposited on top of the light emitting diode (LED) element 153, and the high Ce concentration YAG phosphor 55 is deposited thereon (second region), thereby allowing a higher brightness light emission than in the prior art. In another preferred embodiment, phosphors having different particle sizes or volume densities as illustrated in the second to fifth embodiments may be used.

### Supplement

A wavelength conversion element according to a first aspect of the present invention includes:

a fluorescent layer in which phosphor particles (high Ce concentration YAG phosphor 45, 55, 75, 95, 105a, 105b, or low Ce concentration YAG phosphor 46, 56, 76, 96, 97, 106a, 106b) are dispersed in a binder,

the fluorescent layer including a first region and a second region, the first region being configured to be at a more elevated temperature than the second region due to an effect of excitation light 14,

wherein the phosphor particles (high Ce concentration YAG phosphor 45, 55, 75, 95, 105a, 105b, or low Ce concentration YAG phosphor 46, 56, 76, 96, 97, 106a, 106b) are constituted of a phosphor (YAG:Ce phosphor) doped with a central light emitting element (Ce), and

at least one of a concentration of the central light emitting element (Ce), a size of the phosphor particles (high Ce concentration YAG phosphor 45, 55, 75, 95, 105a, 105b, or low Ce concentration YAG phosphor 46, 56, 76, 96, 97, 106a, 106b), and a volume ratio of the phosphor particles (high Ce concentration YAG phosphor 45, 55, 75, 95, 105a, 105b, or low Ce concentration YAG phosphor 46, 56, 76, 96, 97, 106a, 106b) with respect to the binder is configured to change from the first region to the second region of the fluorescent layer.

According to the configuration described above, it is possible to control the increase in the temperature of the fluorescent layer.

In a wavelength conversion element according to a second aspect of the present invention, in the first aspect described above,

a change in the concentration of the central light emitting element (Ce) is a change in a concentration increasing from the first region to the second region.

According to the configuration described above, heat dissipation can be adjusted by adjusting the dopant concentration, and a high brightness wavelength conversion element can be provided by using a phosphor with a low dopant concentration on the irradiation surface.

In a wavelength conversion element according to a third aspect of the present invention, in the first or second aspect described above,

a change in the size of the phosphor particles (high Ce concentration YAG phosphor 45, 55, 75, 95, 105a, 105b, or low Ce concentration YAG phosphor 46, 56, 76, 96, 97, 106a, 106b) is a change in volume increasing from the first region to the second region.

According to the configuration described above, heat dissipation can be adjusted by adjusting the particle size, and color unevenness on the light emission surface can be reduced by using a phosphor having a small particle size in the light emission surface.

In a wavelength conversion element according to a fourth aspect of the present invention, in any one of the first to third aspects described above,

a change in the volume ratio of the phosphor particles (high Ce concentration YAG phosphor 45, 55, 75, 95, 105a, 105b, or low Ce concentration YAG phosphor 46, 56, 76, 96, 97, 106a, 106b) with respect to the binder is a change in a volume ratio increasing from the first region to the second region,

According to the configuration described above, heat dissipation can be adjusted by adjusting the volume ratio of phosphor particles, and light quantity loss can be reduced depending on the surface shape.

In a wavelength conversion element according to a fifth aspect of the present invention, in any one of the first to fourth aspects described above,

the binder of the fluorescent layer includes voids,

an amount of the binder decreases from the first region to the second region, and

a range of possible amount of the binder in the fluorescent layer includes zero.

According to the configuration described above, heat dissipation can be adjusted by the amount of binder, and light quantity loss can be reduced depending on the surface shape.

In a wavelength conversion element according to a sixth aspect of the present invention, in any one of the first to fifth aspects described above,

the fluorescent layer (35, 36, 47, 115, 116, 131, 148) is configured to change in a thickness across a planar direction,

a change in the thickness is a change in which a thickness of a center of the fluorescent layer is thinner than a thickness of an edge of the fluorescent layer (35, 36, 47, 115, 116, 131, 148),

in a planar direction of the fluorescent layer, the first region is at the center of the fluorescent layer, and the second region is at the edge, and

the first region is at a more elevated temperature than the second region in a planar direction of the fluorescent layer (35, 36, 47, 115, 116, 131, 148) by the excitation light 14 being irradiated to the center of the fluorescent layer (35, 36, 47, 115, 116, 131, 148).

According to the configuration described above, the spot irradiated with the excitation light is smaller than that of the fluorescent layer, and therefore, heat generated at the central portion can be suppressed.

A light source device according to a seventh aspect of the present invention includes:

the wavelength conversion element according to any one of the first to sixth aspects described above; and

a substrate (11, 61, 62, 63),

wherein the fluorescent layer is deposited on the substrate (11, 61, 62, 63),

the fluorescent layer includes a first surface and a second surface opposing to each other in a thickness direction, the first region being on a side of the first surface and the second region being on a side of the second surface,

the second surface faces the substrate (11, 61, 62, 63), and

the first region is at a more elevated temperature than the second region by the excitation light 14 being irradiated from the side of the first surface.

According to the configuration described above, it is possible to provide fluorescent light emission with a higher brightness than in the prior art.

A light source device according to an eighth aspect of the present invention includes:

the wavelength conversion element according to any one of the first to sixth aspects described above; and

a transmissive heat sink substrate 121,

wherein the fluorescent layer is deposited on the transmissive heat sink substrate 121,

the fluorescent layer includes a first surface and a second surface opposing to each other in a thickness direction, the first region being on a side of the first surface and the second region being on a side of the second surface,

the second surface faces the transmissive heat sink substrate 121, and

the first region is at a more elevated temperature than the second region by the excitation light 14 being irradiated from the side of the second surface and heat of the second surface dissipating to the transmissive heat sink substrate 121.

According to the configuration described above, it is possible to provide fluorescent light emission with a higher brightness than in the prior art.

A light source device according to a ninth aspect of the present invention includes:

the wavelength conversion element according to any one of the first to sixth aspects described above; and

a heat sink frame 132,

wherein an edge of the fluorescent layer 131 is held by the heat sink frame 132,

in a planar direction of the fluorescent layer 131, the first region is at a center in the fluorescent layer 131, and the second region is at the edge, and

the first region is at a more elevated temperature than the second region by the excitation light 14 being irradiated to the center of the fluorescent layer 131 and heat of the second region dissipating to the heat sink frame 132.

According to the configuration described above, heat generated in the center (first region) of the disk type fluorescent layer 131 is transferred to the peripheral portion (second region), and heat can be dissipated to the heat sink at the edge.

In a wavelength conversion element according to a 10th aspect of the present invention, in any one of the first to sixth aspects described above,

the binder is constituted of an organic material.

In a wavelength conversion element according to a 11th aspect of the present invention, in any one of the first to sixth aspects described above,

the binder is constituted of an inorganic material.

According to the configuration described above, the binder can be selected for use from a resin material, a transparent inorganic material, or the like depending on the application.

In a wavelength conversion element according to a 12th aspect of the present invention, in the seventh aspect,

in an optical system in which the excitation light 14 is incident from an oblique angle, the fluorescent layer in the first region is elongated with respect to the incident direction.

According to the configuration described above, temperature control can be effectively performed, and it is possible to provide fluorescent light emission with a higher brightness than in the prior art.

A light source device 150 according to a 13th aspect of the present invention includes:

a pair of electrode terminals (lead wires 154);

an excitation light source (light emitting diode (LED) element 153) configured to emit excitation light, the excitation light source being electrically connected to the pair of electrode terminals (lead wires 154); and

the wavelength conversion element according to any one of the first to sixth aspects described above,

wherein the excitation light source (light emitting diode (LED) element 153) is disposed with its primary light emission orientation being oriented upward on a bottom surface of a recessed portion provided in one of the pair of electrode terminals (lead wires 154), and the recessed portion is formed surrounding an outer periphery of the excitation light source (light emitting diode (LED) element 153) disposed on the bottom surface of the recessed portion by a mortar shaped inclined surface,

the wavelength conversion element is provided in the recessed portion covering the excitation light source (light emitting diode (LED) element 153),

the fluorescent layer includes a first surface and a second surface opposing to each other in a thickness direction, the first region being on a side of the first surface and the second region being on a side of the second surface,

the first surface faces toward a side of the excitation light source, and

the first region is at a more elevated temperature than the second region by the excitation light being irradiated from the side of the first surface.

According to the configuration described above, temperature control can be effectively performed, and it is possible to provide LED light emission with a higher brightness than conventional LEDs.

The present invention is not limited to each of the above-described embodiments. it is possible to make various modifications within the scope of the claims. An embodiment obtained by appropriately combining technical elements each disclosed in different embodiments falls also within the technical scope of the present invention. Furthermore, technical elements disclosed in the respective embodiments may be combined to provide a new technical feature.

1. A wavelength conversion element comprising:
a fluorescent layer in which phosphor particles are dispersed in a binder,
the fluorescent layer including a first region and a second region, the first region being configured to be at a more elevated temperature than the second region due to an effect of excitation light,
wherein the phosphor particles are constituted of a phosphor doped with a central light emitting element, and
at least one of a concentration of the central light emitting element, a size of the phosphor particles, and a volume ratio of the phosphor particles with respect to the binder is configured to change from the first region to the second region of the fluorescent layer.

2. The wavelength conversion element according to claim 1,
wherein a change in the concentration of the central light emitting element is a change in a concentration increasing from the first region to the second region.

3. The wavelength conversion element according to claim 1,
wherein a change in the size of the phosphor particles is a change in volume increasing from the first region to the second region.

4. The wavelength conversion element according to claim 1,
wherein a change in the volume ratio of the phosphor particles with respect to the binder is a change in a volume ratio increasing from the first region to the second region.

5. The wavelength conversion element according to claim 1,
wherein the binder of the fluorescent layer includes voids,
an amount of the binder decreases from the first region to the second region, and
a range of possible amount of the binder in the fluorescent layer includes zero.

6. The wavelength conversion element according to claim 1,
wherein the fluorescent layer is configured to change in a thickness across a planar direction,
a change in the thickness is a change in which a thickness of a center of the fluorescent layer is thinner than a thickness of an edge of the fluorescent layer,
in a planar direction of the fluorescent layer, the first region is at the center of the fluorescent layer, and the second region is at the edge, and
the first region is at a more elevated temperature than the second region in a planar direction of the fluorescent layer by the excitation light being irradiated to the center of the fluorescent layer.

7. A light source device comprising:
the wavelength conversion element according to claim 1; and
a substrate,
wherein the fluorescent layer is deposited on the substrate,
the fluorescent layer includes a first surface and a second surface opposing to each other in a thickness direction, the first region being on a side of the first surface and the second region being on a side of the second surface,
the second surface faces the substrate, and
the first region is at a more elevated temperature than the second region by the excitation light being irradiated from the side of the first surface.

8. A light source device comprising:
the wavelength conversion element according to claim 1; and
a transmissive heat sink substrate,
wherein the fluorescent layer is deposited on the transmissive heat sink substrate,
the fluorescent layer includes a first surface and a second surface opposing to each other in a thickness direction, the first region being on a side of the first surface and the second region being on a side of the second surface,
the second surface faces the transmissive heat sink substrate, and
the first region is at a more elevated temperature than the second region by the excitation light being irradiated from the side of the second surface and heat of the second surface dissipating to the transmissive heat sink substrate.

9. A light source device comprising:
the wavelength conversion element according to claim 1; and
a heat sink frame,
wherein an edge of the fluorescent layer is held by the heat sink frame,
in a planar direction of the fluorescent layer, the first region is at a center in the fluorescent layer, and the second region is at the edge, and
the first region is at a more elevated temperature than the second region by the excitation light being irradiated to the center of the fluorescent layer and heat of the second region dissipating to the heat sink frame.

10. A light source device comprising:
a pair of electrode terminals;
an excitation light source configured to emit excitation light, the excitation light source being electrically connected to the pair of electrode terminals; and
the wavelength conversion element according to claim 1,
wherein the excitation light source is disposed with its primary light emission orientation being oriented upward on a bottom surface of a recessed portion provided in one of the pair of electrode terminals, and the recessed portion is formed surrounding an outer periphery of the excitation light source disposed on the bottom surface of the recessed portion by a mortar shaped inclined surface,
the wavelength conversion element is provided in the recessed portion covering the excitation light source,
the fluorescent layer includes a first surface and a second surface opposing to each other in a thickness direction, the first region being on a side of the first surface and the second region being on a side of the second surface,
the first surface faces toward a side of the excitation light source, and
the first region is at a more elevated temperature than the second region by the excitation light being irradiated from the side of the first surface.
